(19) United States
(12) Patent Application Publication
(10) Pub. No.: US 2008/0211590 A1
(43) Pub. Date: Sep. 4, 2008

(54) METHOD AND SYSTEM FOR A VARACTOR-TUNED VOLTAGE-CONTROLLED RING OSCILLATOR WITH FREQUENCY AND AMPLITUDE CALIBRATION

(76) Inventor: Stephen Wu, Fountain Valley, CA (US)

Correspondence Address: MCANDREWS HELD & MALLOY, LTD, 500 WEST MADISON STREET, SUITE 3400, CHICAGO, IL, 60661, US

(21) Appl. No.: 11/680,883

(22) Filed: Mar. 1, 2007

(51) Int. Cl. H03K 3/02

(52) U.S. Cl. 331/57

(57) ABSTRACT

Aspects of a method and system for a varactor-tuned voltage-controlled ring oscillator with frequency and amplitude calibration may include generating in a voltage controlled ring oscillator, an oscillating signal using delay cells, wherein each delay cell may comprise varactors and variable resistors. The frequency of the generated oscillating signal may be variable and may be calibrated by calibrating a delay associated with the delay cells. The amplitude of the generated oscillating signal may be calibrated by adjusting variable resistors and current sources within the delay cells. The frequency of the generated oscillating signal may be varied by varying the delay of at least one delay cell through changing the capacitance of its varactors. Changing a control voltage may change the varactor capacitance. The gain of the ring oscillator may be reduced by adjusting the varactors, and the generated oscillating signal may be a square wave signal.

### CROSS-REFERENCE TO RELATED APPLICATIONS/INCORPORATION BY REFERENCE

None

### FIELD OF THE INVENTION

Certain embodiments of the invention relate to electronic circuit design. More specifically, certain embodiments of the invention relate to a method and system for a varactor-tuned voltage-controlled ring oscillator with frequency and amplitude calibration.

### BACKGROUND OF THE INVENTION

A circuit that generates a signal for which an oscillating frequency of the signal is proportional to an applied voltage may be referred to as a voltage controlled oscillator (VCO). A device for which the capacitance value varies based on an applied voltage may be known as a variable reactance, or varactor. Varactors may also be referred to as varicap diodes or tuning diodes. In some VCO implementations, the oscillating frequency of a VCO may be controlled by a varactor. The value of the VCO gain, Kvco, may control the amount by which the oscillating frequency of a time-varying signal generated by a VCO may change based on a change in the voltage level of a control signal.

VCOs may be used in a wide variety of applications and they may be a main building block of Phase-Locked Loops (PLLs). PLLs are electronic feedback circuits that may be used to track, for example, the frequency changes in an FM modulated signal and may be used as demodulator and a variety of other applications in communication systems.

Some VCO implementations may use LC circuits for the oscillating element. However, inductors may occupy much die area in integrated circuit implementations due to their physical size. Accordingly, in some Integrated Circuit (IC) applications, the use of inductors may be undesirable, especially in instance where the die size may be relatively small.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A method and/or system for a varactor-tuned voltage-controlled ring oscillator with frequency and amplitude calibration, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary implementation of a Phase-Locked Loop (PLL) comprising a Voltage-Controlled Oscillator (VCO), in connection with an embodiment of the invention.

FIG. 2A is a block diagram illustrating an exemplary time-delay voltage-controlled oscillator, in accordance with an embodiment of the invention.

FIG. 2B is a diagram illustrating timing associated with the time-delay voltage controlled oscillator of FIG. 2A, in accordance with an embodiment of the invention.

FIG. 3 is a block diagram illustrating an exemplary voltage-controlled ring oscillator comprising a plurality of inverters, in accordance with an embodiment of the invention.

FIG. 4 is a circuit diagram illustrating an exemplary delay-cell inverter with a varactor and a calibrated resistor, in accordance with an embodiment of the invention.

### DETAILED DESCRIPTION OF THE INVENTION

Certain embodiments of the invention may be found in a method and system for a varactor-tuned voltage-controlled ring oscillator with frequency and amplitude calibration. Aspects of a method and system for a varactor-tuned voltage-controlled ring oscillator with frequency and amplitude calibration may include generating in a voltage controlled ring oscillator, an oscillating signal using delay cells, wherein each delay cell may comprise varactors and variable resistors. The frequency of the generated oscillating signal may be variable and may be calibrated by calibrating a delay associated with the delay cells. The amplitude of the generated oscillating signal may be calibrated by adjusting variable resistors and current sources within the delay cells. The frequency of the generated oscillating signal may be varied by varying the delay of at least one delay cell through changing the capacitance of its varactors. Changing a control voltage may change the varactor capacitance. The frequency may also be changed by changing a resistance associated with one or more of the variable resistors. The gain of the ring oscillator may be reduced by adjusting the varactors, and the generated oscillating signal may be a square wave signal. The ring oscillator may comprise one or more delay cells of which at least one may invert its input signal.

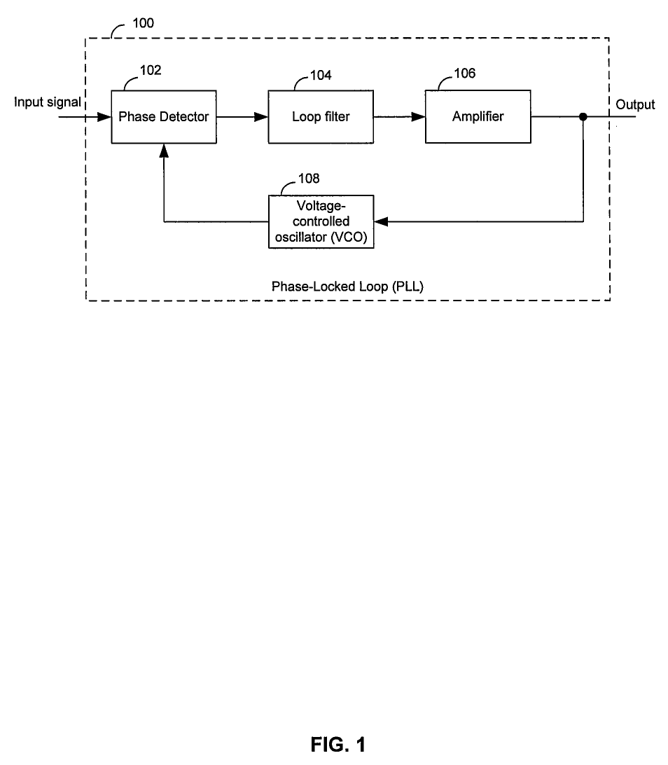

FIG. 1 is a block diagram illustrating an exemplary implementation of a Phase-Locked Loop (PLL) 100 comprising a Voltage-Controlled Oscillator (VCO), in connection with an embodiment of the invention. Referring to FIG. 1, there is shown a PLL 100, comprising a phase detector 102, a loop filter 104, an amplifier 106 and a VCO 108. There is also shown an input signal, which may be supplied to the phase detector 102 and an output signal from PLL 100, which may be generated from the output of the amplifier 106.

The VCO 108 may comprise suitable logic, circuitry and/or code that may be enabled to generate an oscillating output signal whose frequency may be proportional to an externally applied voltage that may be fed to the VCO 108 from the output signal. When the PLL 100 is in locked condition, the VCO 108 may oscillate at a frequency that may be equal to the frequency of the input signal. An oscillating output signal generated by the VCO 108 may be supplied as an input to the phase detector 102.

The phase detector 102 may comprise suitable logic, circuitry and/or code that may be enabled to generate an output signal that may be proportional to the phase difference between the input signal and the VCO 108 output signal. The output signal generated by the phase detector 102 may be a phase sensitive signal. This phase-sensitive signal may then be supplied as in input to the loop filter 104.

The loop filter 104 may comprise suitable logic, circuit and/or code that may be enabled to receive and filter the output signal that may be generated by the phase detector 102. The loop filter 104 may generate an output filtered signal, which may be provided as an input to the amplifier 106.

The amplifier 106 may comprise suitable logic circuitry and/or code that may be enabled to amplify the filtered output signal generated by the loop filter 104. The amplifier 106 may be enabled to generate an amplified output signal, which may be the output signal generated by the PLL 100. The amplified output signal generated by the amplifier 106y may be a control signal, which may be fed back to an input of the VCO 108.

Due to this feedback loop structure of the PLL 100, the VCO 108 may track frequency changes of the input signal and the output signal may be proportional to the frequency of the input signal. This behavior may be exploited, for example, for the demodulation of FM signals or in a large variety of communication systems. The range of frequencies over which this behavior for the PLL 100 may be true may be called the lock range. The range of input frequencies over which the PLL 100 may be able to capture the input signal and lock onto it may be called the capture range. The objective of the loop filter 104 may be to remove difference components that may be far removed from the center frequency of the VCO 108. Reducing the loop filter 104 bandwidth may improve the rejection of out-of-band interference but it may also reduce the capture range and may increase the time for the PLL 100 to reach steady state. The time to reach steady state may be referred to as the settling time. Correspondingly, the loop filter 104 design may be important to the overall performance characteristics of the PLL 100, as may be the design of the VCO 108.

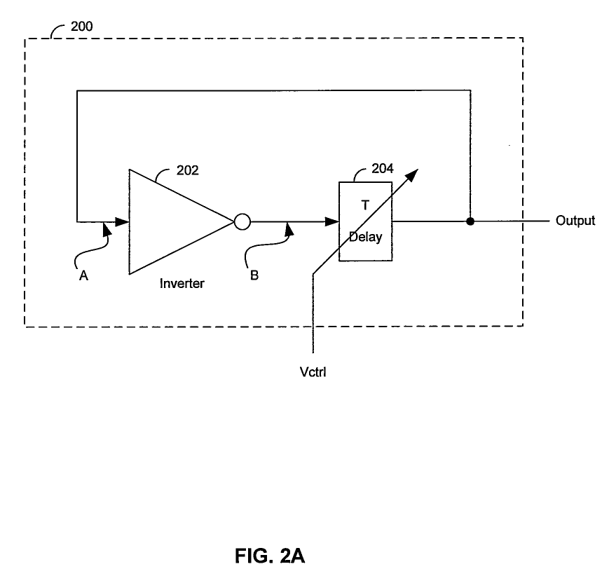

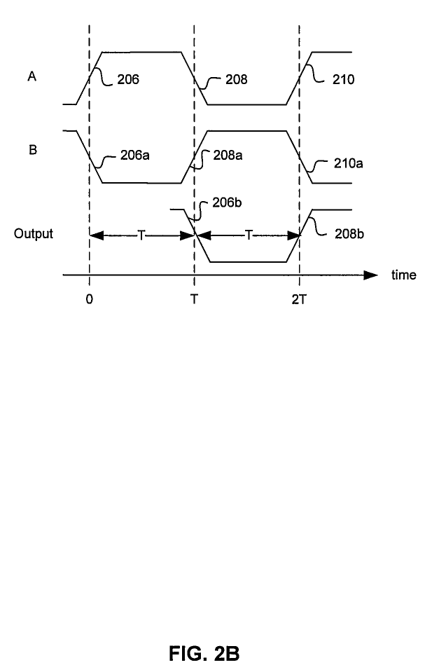

FIG. 2A is a block diagram illustrating an exemplary time-delay voltage-controlled oscillator, in accordance with an embodiment of the invention. Referring to FIG. 2A, there is shown a time-delay VCO 200, comprising an inverter 202 and a voltage-controlled delay element 204. There is also shown an output signal, signal A at the input of the inverter and signal B at the output of the inverter, and a control voltage, Vctrl. The output of the inverter 202 may be coupled to an output of the voltage-controlled delay element 204. The output of the voltage-controlled delay element 204 may be feedback to an input of the inverter 202.

FIG. 2B is a diagram illustrating timing associated with the time-delay voltage controlled oscillator of FIG. 2A, in accordance with an embodiment of the invention. Referring to FIG. 2B, there is shown the signal A, the signal B, and an output signal. The signal A is an input to the inverter 202, the signal B is an output of the inverter 202, and the output signal is generated by the voltage controlled delay element 204. The signal A comprises amplitude transitions 206, 208 and 210, the signal B comprises amplitude transitions 206a, 208a and 210a and the output signal comprises amplitude transitions 206b and 208b.

In accordance with an embodiment of the invention, the operation of the time-delay VCO 200 may be explained by considering the signals A, B and output in response to an amplitude transition. The inverter 202 may be assumed to be instantaneous, that is, its output may invert its input without delay. Although physical devices may not be instantaneous, the delay of the inverter 202 may be considered included in the delay of the voltage-controlled delay element 204. The voltage-controlled delay element 204 may delay its input signal, signal B, by T seconds as illustrated in FIG. 2B, where T may be a function of the control voltage, Vctrl, which may be applied to the voltage-controlled delay element 204.

With reference the FIG. 2A and FIG. 2B, at the input of the inverter 202, an amplitude transition 206 from low to high may occur for signal A at time 0. At the output of the inverter 202, the signal B may therefore transition from high to low as shown in amplitude transition 206a. Since the voltage-controlled delay element 204 may delay the signal B by T seconds by, the amplitude transition 206a may only appear at the output at time T, depicted by transition 206b. Due to the instantaneous feedback from the output of the voltage-controlled delay element 204 back to the input of the inverter 202, signal A will transition from high to low and 206b may become transition 208 at signal A. This in turn may trigger the inverter 202 and toggle the inverter 202 output, as shown by the transition 208a. Due to the delay of the voltage-controlled delay element 204, the transition 208b may show up at the output signal at time 2T. This process may continue as described and may therefore produce a square-wave oscillator. The inverter 202 may have a gain greater than one to sustain oscillation. As illustrated in FIG. 2, the output signal generated by the voltage-controlled delay element 204 has period 2T. Hence, the delay T may control the oscillation frequency of the time-delay VCO 200. By varying T via the control voltage Vctrl, the frequency of the time-delay VCO 200 may be adjusted.

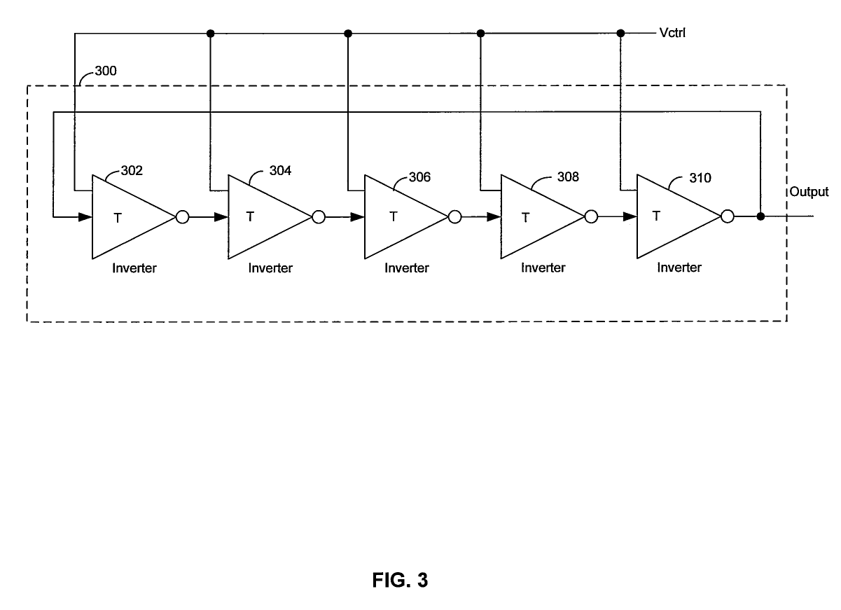

FIG. 3 is a block diagram illustrating an exemplary voltage-controlled ring oscillator comprising a plurality of inverters, in accordance with an embodiment of the invention. Referring to FIG. 3, there is shown a voltage-controlled ring oscillator 300, comprising of variable delay inverters 302, 304, 306, 308 and 310. There is also shown in FIG. 3, an output signal and a control signal Vctrl.

The output of the inverter 302 may be coupled to the input of the inverter 304. The output of the inverter 304 may be coupled to the input of the inverter 306. The output of the inverter 306 may be coupled to the input of the inverter 308. The output of the inverter 308 may be coupled to the input of the inverter 310. The output of the inverter 308 may be coupled to the input of the inverter 302. The Inverters 302, 304, 306, 308 and 310 may be coupled to Vctrl. Vctrl may be a voltage signal that may control the delay T in the delay cells 302, 304, 306, 308 and 310.

The voltage-controlled oscillator 300 may be a distributed implementation of the time-delay oscillator 200, shown in FIG. 2. The functionality of the voltage-controlled oscillator 300 may be similar to the time-delay oscillator 200, where the overall delay may be distributed over the inverters. The inverters 302, 304, 306, 308 and 310 may each comprise an inverter 202 and a time delay element 204 as illustrated in FIG. 2. The output of an inverter may be the negative of its input signal, delayed by T seconds. By combining a number of inverters, the overall delay of the voltage-controlled oscillator 300 may be the sum of the delays of the inverters 302 through 310. The overall gain of the inverters 302 through 310 may be greater than unity. The voltage-controlled ring oscillator 300 may be implemented with an arbitrary odd number of inverters to enable the feedback signal to be an inverted and delayed copy of the input signal to the first inverter, inverter 302 as illustrated in FIG. 3. After an initial start-up period, the output signal of the voltage-controlled oscillator 300 may be a square wave with period 10T, since each inverter may delay the signal by T seconds, introducing a total delay of 5T seconds. As explained in FIG. 2B, the oscillating period may be twice the length of the total delay. In general, the period may be 2NT seconds, where N may be the number of inverters and T may be the delay of each inverter.

Some implementations of voltage-controlled oscillators may use LC-circuits instead of ring the oscillators due to the high quality (Q) factor achievable. However, in accordance with various embodiments of the invention, the voltage controlled oscillators may be implemented in integrated circuits using ring oscillators since the ring oscillators utilize much less die area than LC-circuits because of the absence of inductors.

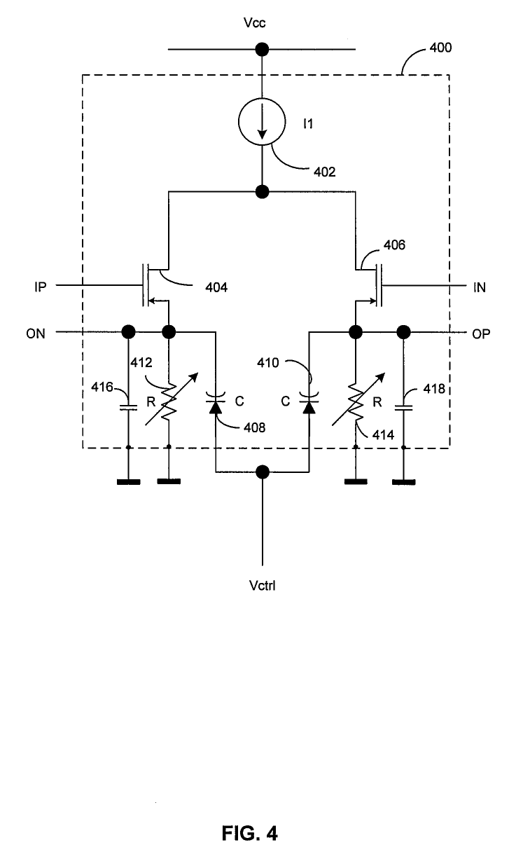

FIG. 4 is a circuit diagram illustrating an exemplary delay-cell inverter with a varactor and a calibrated resistor, in accordance with an embodiment of the invention. Referring to FIG. 4, there is shown a delay cell 400, a current source 402, MOSFETs 404 and 406, varactors 408 and 410, resistors R 412 and 414, and capacitors 416 and 418. There is also shown input signals IP, IN and control voltage Vctrl, output signals ON and OP, and supply voltage Vcc.

The input signal IP may be coupled to the gate of THE MOSFET 404. The drain of the MOSFET 404 may be coupled to one terminal of the current source 402. The other terminal of the current source 402 may be coupled to the supply voltage VCC. The drain of the MOSFET 404 may also be coupled to the drain of the MOSFET 406. The input signal IN may be coupled to the gate of the MOSFET 406. The source of the MOSFET 406 may be coupled to one terminal of the capacitor 418, one terminal of the variable resistor 414 and the cathode of the varactor 410. The other terminal of the capacitor 418 and the variable resistor 414 may be coupled to ground. The source of the MOSFET 404 may be coupled to one terminal of the capacitor 416, one terminal of the variable resistor 412, and the cathode of the varactor 408. The other terminal of the capacitor 416 and the variable resistor 412 may be coupled to ground. The output signal ON may be obtained at the source of the MOSFET 404 and the output signal OP may be obtained at the source of the MOSFET 406. The anodes of the varactors 408 and 410 may be coupled to Vctrl.

The input to the delay cell 400 may be differential, using the positive and negative terminal IP and IN, respectively. The output may also be differential, comprising signals ON and OP. The varactors 408 and 410 may behave like voltage-controlled capacitors, where the capacitance C may depend on the voltage across the varactor diodes and therefore the voltage Vctrl. Capacitors 416 and 418 may be due to parasitic effects.

In operation, in instances when the input voltage at positive terminal IP transitions to high and the voltage at the negative terminal IN transitions to low, the MOSFET 406 may act like a closed switch whereas the MOSFET 404 may act like an open switch. Hence, the current 11 from current source 402 may be routed through MOSFET 406. Initially, the current through MOSFET 406 may flow into varactor 410, which may act like an initially discharged capacitor C. As the varactor 410 may begin to charge, the current into varactor 410 may decrease while the current through resistor 414 may increase, and thereby the output voltage OP may increase. Due to the charging action of the varactor 410, the resistor R 414 and the varactor 410 with capacitance C may form an RC circuit that may delay the voltage transition from IP/IN to appear at OP/ON. Hence, the differential output voltage from OP to ON may be proportional and delayed to the differential input voltage from IP to IN. To obtain inversion from delay cell 400, the differential output voltage from ON to OP may be utilized. If the input voltage transition is for IP to low and for IN to high, the current will flow through the MOSFET 404 and the varactor 408 and the resistor 412 will form a delay element instead.

An advantage of this embodiment of the invention may be the absence of inductors. Since the varactor capacitance C may be controlled by the voltage Vctrl and a delay T of the delay cell 400 may be approximately 1/RC, the oscillation frequency may be directly controlled by Vctrl and the varactors 408 and 410, thereby avoiding a voltage-to-current conversion circuit that may be required for some implementations of voltage-controlled oscillators. Due to a reduced number of components of this embodiment of the invention when compared to some implementations of voltage-controlled oscillators, phase noise may be substantially reduced. In order to enable precise control of the time delay, it may be necessary to use well-calibrated and/or adjustable resistors R 412 and 414. If both the resistors R 412 and 414 may be calibrated along with the current source I1 402, the result may be improved amplitude stability that may further reduce phase noise.

The gain of a voltage-controlled oscillator, Kvco, may be a function of the delay cell 400. By lowering Kvco, the range of frequencies over which the PLL 100 shown in FIG. 1 may operate, may be reduced since the frequency range of the PLL may be proportional to the gain Kvco. A lower frequency range at the PLL, however, may reduce the phase noise. Since Kvco may be proportional to C/(C+Cf), where C may be the capacitance of the varactors 408 and 410, and Cf may be the fixed capacitance due to parasitic effects of the capacitors 416 and 418, the gain Kvco may be varied through the capacitance C of the varactors 408 and 410. A reduced Kvco may also permit to use physically smaller components, in particular capacitors, in an implementation of the loop filter 104, shown in FIG. 1.

In accordance with an embodiment of the invention, a method and system for a varactor-tuned voltage-controlled ring oscillator with frequency and amplitude calibration may include generating in a voltage controlled ring oscillator 300, an oscillating signal using delay cells 400, wherein each delay cell 400 may comprise varactors 408 or 410 and variable resistors 412 or 414, as illustrated in FIG. 3 and FIG. 4. The frequency of the generated oscillating signal may be variable and may be calibrated by calibrating a delay 204 associated with the delay cells 200, as explained in FIG. 2A and FIG. 2B. The amplitude of the generated oscillating signal may be calibrated by adjusting variable resistors 412 and 414 and current source 402 within the delay cells 400, as illustrated in FIG. 4. The frequency of the generated oscillating signal may be varied by varying the delay of at least one delay cell, for example delay cell 302, 304, 306, 308 and 310 in FIG. 3, through changing the capacitance of its varactors. Changing a control voltage, Vctrl in FIG. 3 or FIG. 4, may change the varactor capacitance. The frequency may also be changed by changing a resistance of one or more of the variable resistors 412 or 414 illustrated in FIG. 4. The gain of the ring oscillator 300 may be reduced by adjusting the varactors, and the generated oscillating signal may be a square wave signal, as explained in FIG. 2A/2B, FIG. 3 and FIG. 4. The ring oscillator 400 may comprise one or more delay cells of which at least one may invert its input signal.

Another embodiment of the invention may provide a machine-readable storage, having stored thereon, a computer program having at least one code section executable by a machine, thereby causing the machine to perform the steps as described above for a varactor-tuned voltage-controlled ring oscillator with frequency and amplitude calibration.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for processing electrical signals, the method comprising:
generating in a voltage controlled ring oscillator, an oscillating signal using a plurality of delay cells, wherein each of said delay cells comprises a plurality of varactors and a plurality of variable resistors.

2. The method according to claim 1, wherein a frequency of said generated oscillating signal is variable.

3. The method according to claim 1, comprising calibrating a frequency of said generated oscillating signal by calibrating a delay associated with one or more of said plurality of delay cells.

4. The method according to claim 1, comprising calibrating an amplitude of said generated oscillating signal by adjusting a resistance of one or more of said plurality of variable resistors and a plurality of current sources within said plurality of delay cells.

5. The method according to claim 1, comprising varying a frequency of said generated oscillating signal by adjusting a delay associated with at least one of said plurality of delay cells.

6. The method according to claim 5, comprising adjusting said delay of said at least one of said plurality of delay cells by changing capacitance of at least one of said plurality of varactors.

7. The method according to claim 6, comprising changing said capacitance of said at least one of said plurality of varactors by changing a control voltage.

8. The method according to claim 5, comprising adjusting said delay of said at least one of said plurality of delay cells by changing a resistance of at least one of said plurality of variable resistors.

9. The method according to claim 1, comprising reducing a gain of said ring oscillator by adjusting said plurality of varactors.

10. The method according to claim 1, wherein said generated oscillating signal comprises a square wave signal.

11. The method according to claim 1, wherein said voltage-controlled ring oscillator comprises one or more of said delay cells.

12. The method according to claim 1, comprising inverting an input signal of at least one of said delay cell at the output of said at least one delay cell.

13. A system for processing electrical signals, the system comprising:
a voltage controlled ring oscillator capable of generating an oscillating signal using a plurality of delay cells, wherein each of said delay cells comprises a plurality of varactors and a plurality of variable resistors.

14. The system according to claim 13, wherein a frequency of said generated oscillating signal is variable.

15. The system according to claim 13, wherein said voltage controlled ring oscillator calibrates a frequency of said generated oscillating signal by calibrating a delay associated with one or more of said plurality of delay cells.

16. The system according to claim 13, wherein said voltage controlled ring oscillator calibrates an amplitude of said generated oscillating signal by adjusting a resistance of one or more of said plurality of variable resistors and a plurality of current sources within said plurality of delay cells.

17. The system according to claim 13, wherein said voltage controlled ring oscillator varies a frequency of said generated oscillating signal by adjusting a delay associated with at least one of said plurality of delay cells.

18. The system according to claim 17, wherein said voltage controlled ring oscillator adjusts said delay of said at least one of said plurality of delay cells by changing capacitance of at least one of said plurality of varactors.

19. The system according to claim 18, wherein said voltage controlled ring oscillator changes said capacitance of said at least one of said plurality of varactors by changing a control voltage.

20. The system according to claim 17, wherein said voltage controlled ring oscillator adjusts said delay of said at least one of said plurality of delay cells by changing a resistance of at least one of said plurality of variable resistors.

21. The system according to claim 13, wherein said voltage controlled ring oscillator reduces a gain of said ring oscillator by adjusting said plurality of varactors.

22. The system according to claim 13, wherein said generated oscillating signal comprises a square wave signal.

23. The system according to claim 13, wherein said voltage-controlled ring oscillator comprises one or more of said delay cells.

24. The system according to claim 13, wherein said voltage controlled ring oscillator inverts an input signal of at least one of said delay cell at the output of said at least one delay cell.
